(19) United States
(12) Patent Application Publication
(10) Pub. No.: US 2024/0105531 A1
(43) Pub. Date: Mar. 28, 2024

(54) DISPLAY MODULE AND METHOD FOR ATTACHING DISPLAY MODULE AND WINDOW MEMBER

(71) Applicant: Samsung Display Co., LTD., Yongin-si (KR)

(72) Inventors: YOUNGSU KIM, Yongin-si (KR); CHEULJIN PARK, Yongin-si (KR); KISANG YOO, Yongin-si (KR)

(21) Appl. No.: 18/225,330

(22) Filed: Jul. 24, 2023

(30) Foreign Application Priority Data
Sep. 28, 2022 (KR) 10-2022-0123768

(51) Int. Cl. H01L 23/13; H01L 25/16; H10K 59/80

(52) U.S. Cl. CPC H01L 23/13; H01L 25/167; H10K 59/873

(57) ABSTRACT

A display module includes a display member including a flat portion and a bending portion bent while extending from the flat portion and a guide film disposed on a rear surface of the display member and including an extended portion extending from an edge of the display member in a plan view. The guide film is provided with an opening defined therein to overlap the bending portion.

This application claims priority to Korean Patent Application No. 10-2022-0123768, filed on Sep. 28, 2022, and all the benefits accruing therefrom under 35 U.S.C. § 119, the content of which in its entirety is herein incorporated by reference.

### BACKGROUND

### 1. Field

Embodiments of the disclosure described herein relate to a display module including a bending region and a method for attaching the display module and a window member.

### 2. Description of the Related Art

Multimedia devices, such as a television, a mobile phone, a tablet computer, a car navigation device, a game machine, and the like, may include a display device for displaying an image. Recently, with the development of display device technology, various forms of display devices have been developed. For example, the display device may display an image through a display surface including a curved surface.

### SUMMARY

A display device may be manufactured by laminating a window member and a display module including a display panel. A display device including a curved surface may be formed by attaching a display module and a window member, each of which has a curved surface. In such a display device, since each of the display module and the window member has the curved surface, curved portions of the display module and the window member may not be completely bonded to each other, or may be damaged due to low durability, in a lamination process.

Embodiments of the disclosure provide a display module for preventing a defect in a process of attaching the display module and a window member to each other and damage to the display member, and a method for attaching the display module and the window member to each other.

According to an embodiment, a display module includes a display member including a flat portion and a bending portion bent while extending from the flat portion and a guide film disposed on a rear surface of the display member, where the guide film includes an extended portion extending from an edge of the display member in a plan view. In such an embodiment, the guide film is provided with an opening defined therein to overlap the bending portion of the display module.

In an embodiment, the flat portion may include a first side extending in a first direction, and the bending portion may include a first bending portion bent while extending from the first side of the flat portion.

In an embodiment, the flat portion may include a second side extending in the first direction and opposite to the first side in a second direction crossing the first direction, and the bending portion may further include a second bending portion bent while extending from the second side of the flat portion.

In an embodiment, the flat portion may include a third side and a fourth side extending in the second direction and opposite to each other in the first direction, and the bending portion may further include a third bending portion and a fourth bending portion bent while extending from the third side and the fourth side of the flat portion, respectively.

In an embodiment, the opening may include first to fourth openings which overlap the first to fourth bending portions, respectively.

In an embodiment, the first opening and the second opening may extend in the first direction, and the third opening and the fourth opening may extend in the second direction.

In an embodiment, the first opening may be provided in plural, and a plurality of first openings may be arranged in the second direction while overlapping the first bending portion.

In an embodiment, the first opening may be provided in plural, and each of a plurality of first openings may extend in the second direction, and the first openings may be arranged in the first direction while overlapping the first bending portion.

In an embodiment, the guide film may include first to fourth extended portions disposed on rear surfaces of the first to fourth bending portions, respectively. In such an embodiment, the first extended portion and the second extended portion may be spaced apart from each other in the second direction with the flat portion therebetween, and the third extended portion and the fourth extended portion may be spaced apart from each other in the first direction with the flat portion therebetween.

In an embodiment, the flat portion may include a first flat portion and a second flat portion which overlap each other in a plan view, and the bending portion may be disposed between the first flat portion and the second flat portion and may be connected to the first flat portion and the second flat portion.

In an embodiment, the bending portion may extend in a first direction, and the opening may extend in the first direction.

In an embodiment, a length of the opening may be shorter than a length of the bending portion in the first direction.

In an embodiment, a width of the opening may be greater than a width of the bending portion in a second direction crossing the first direction.

In an embodiment, the opening may extend to opposite ends of the guide film in the first direction, and the guide film may include a plurality of portions spaced apart from each other with the opening therebetween.

In an embodiment, the opening may be provided in plural, and a plurality of openings may be arranged in a second direction crossing the first direction.

In an embodiment, the bending portion may extend in a first direction. In such an embodiment, the opening may be provided in plural, each of a plurality of openings may extend in a second direction crossing the first direction, and the openings may be arranged in the first direction.

In an embodiment, the display member may include a base layer, a circuit layer disposed on the base layer, a display element layer disposed on the circuit layer, and an encapsulation layer that seals the display element layer.

In an embodiment, the display member may further include at least one selected from an input sensing layer and an anti-reflection layer disposed on the encapsulation layer.

In an embodiment, the display module may further include an adhesive layer disposed on the display member and a window member disposed on the adhesive layer.

According to an embodiment, a method for attaching a display module and a window member to each other includes providing a pressure pad including a pressure surface including a curved surface, providing the display module including an adhesive layer, a display member, and a guide film on the pressure pad, providing a jig with the window member disposed thereon on the display module, and attaching the display module and the window member to each other through the adhesive layer. In such an embodiment, the display member includes a bending portion that overlaps the curved surface of the pressure pad, and the guide film is provided with an opening defined therein to overlap the bending portion of the display member.

### BRIEF DESCRIPTION OF THE DRAWINGS

The above and other features of embodiments of the disclosure will become apparent by describing in detail embodiments thereof with reference to the accompanying drawings.

FIG. 1 is a perspective view of a display device according to an embodiment of the disclosure.

FIG. 2 is an exploded perspective view of the display device illustrated in FIG. 1.

FIGS. 3A and 3B are perspective views of a display device according to an embodiment of the disclosure.

FIG. 4 is an exploded perspective view of the display device illustrated in FIG. 3A.

FIGS. 5A and 5B are sectional views of a display member according to an embodiment of the disclosure.

FIGS. 6A to 6C are sectional views illustrating a method of attaching a display module and a window member to each other according to an embodiment of the disclosure.

FIG. 7A is a sectional view of a display module according to an embodiment of the disclosure.

FIG. 7B is a sectional view of a display module according to a comparative example.

FIGS. 8A to 8D are perspective views of a display module according to embodiments of the disclosure.

FIGS. 9A to 9C are sectional views illustrating a method of attaching a display module and a window member to each other according to an embodiment of the disclosure.

FIGS. 10A to 10G are perspective views of a display module according to embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when it is mentioned that a component (or, a region, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display module and a method for attaching the display module and a window member to each other according to embodiments of the disclosure will be described in detail with reference to the accompanying drawings.

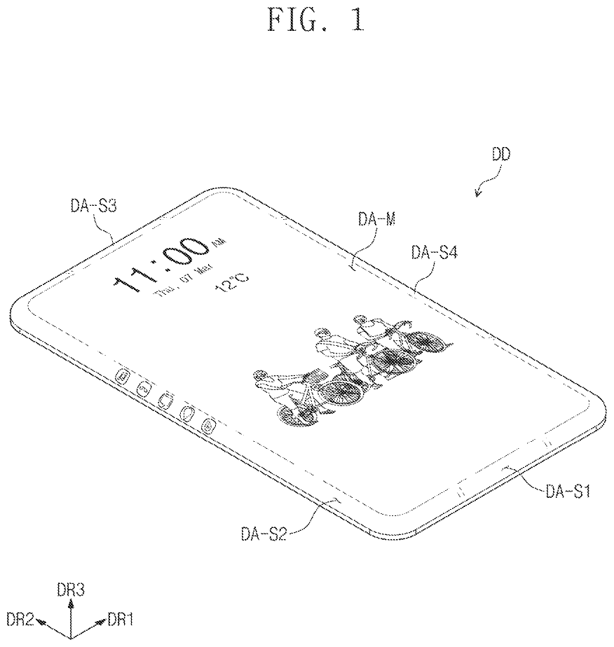

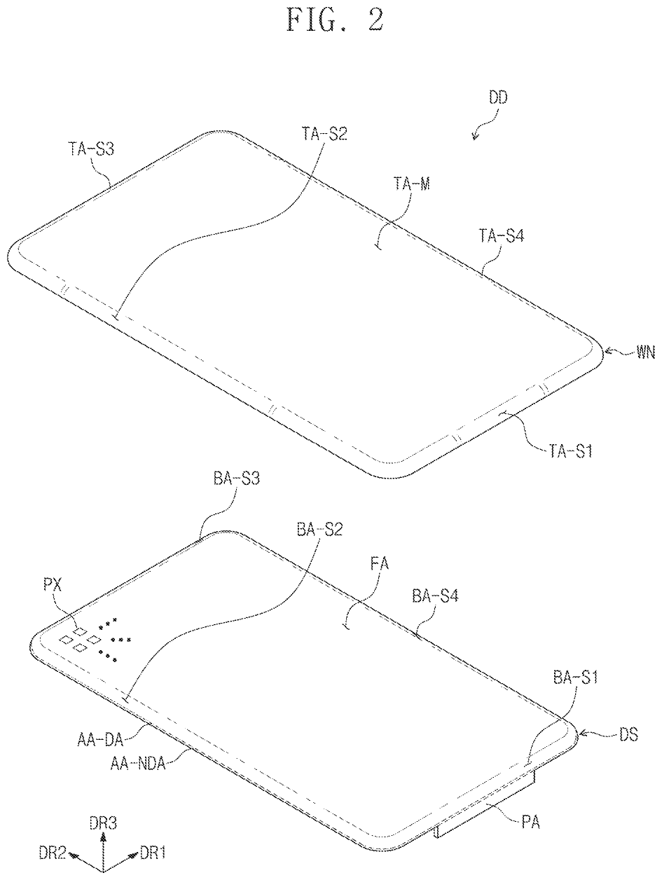

FIG. 1 is a perspective view of a display device DD according to an embodiment of the disclosure. FIG. 2 is an exploded perspective view of the display device DD illustrated in FIG. 1.

Referring to FIGS. 1 and 2, the display device DD may be a device that is activated in response to an electrical signal and that displays an image. In an embodiment, for example, the display device DD may include a device such as a monitor, a mobile phone, a tablet computer, a car navigation device, or a game machine. However, the embodiments of the display device DD are illustrative, and the display device DD is not limited to any one as long as it does not deviate from the spirit and scope of the disclosure. In an embodiment, as shown in FIGS. 1 and 2, the display device DD may be a smart phone.

A display region may be defined on the display device DD. The display device DD may display an image through the display region and may receive an external input through the display region. In an embodiment, the display region of the display device DD may include a main display region DA-M and first to fourth sub-display regions DA-S1, DA-S2, DA-S3, and DA-S4.

The main display region DA-M may be on a plane substantially parallel to a plane defined by a first direction DR1 and a second direction DR2. Alternatively, without being limited thereto, the main display region DA-M may have a shape concavely or convexly curved with respect to the plane defined by the first direction DR1 and the second direction DR2.

The main display region DA-M may display the image in a third direction DR3 crossing the first direction DR1 and the second direction DR2. Front surfaces (or, upper surfaces) and rear surfaces (or, lower surfaces) of members constituting the display device DD may be opposite each other in the third direction DR3, and the third direction DR3 may be defined as a thickness direction of the display device DD.

The expression “in a plan view” used herein may mean that it is viewed in the third direction DR3. The expression “on a section” used herein may mean that it is viewed in the first direction DR1 or the second direction DR2. In embodiments of the disclosure, the directions indicated by the first, second, and third directions DR1, DR2, and DR3 may be relative concepts and may be changed to different directions.

In an embodiment, the main display region DA-M may have a rectangular shape with short sides extending in the first direction DR1 and long sides extending in the second direction DR2. Alternatively, without being limited thereto, the main display region DA-M may have various shapes, such as a circular shape, a polygonal shape, and the like, in a plan view.

The first to fourth sub-display regions DA-S1, DA-S2, DA-S3, and DA-S4 may be bent from the main display region DA-M. Each of the first to fourth sub-display regions DA-S1, DA-S2, DA-S3, and DA-S4 may be bent with a curvature and may include a curved surface. The first to fourth sub-display regions DA-S1, DA-S2, DA-S3, and DA-S4 may have a same curvature or a same radius of curvature as each other. Alternatively, without being limited thereto, at least some of the first to fourth sub-display regions DA-S1, DA-S2, DA-S3, and DA-S4 may have different curvatures from another thereof.

The main display region DA-M and the first to fourth sub-display regions DA-S1, DA-S2, DA-S3, and DA-S4 may be adjacent to each other and may implement a continuous display region. The first to fourth sub-display regions DA-S1, DA-S2, DA-S3, and DA-S4 may be connected with each other and may surround the main display region DA-M. The first sub-display region DA-S1 and the third sub-display region DA-S3 may extend from the short sides of the main display region DA-M that are parallel to the first direction DR1, and the second sub-display region DA-S2 and the fourth sub-display region DA-S4 may extend from the long sides of the main display region DA-M that are parallel to the second direction DR2.

FIG. 1 illustrates an embodiment including the four sub-display regions DA-S1, DA-S2, DA-S3, and DA-S4 extending from the four sides of the main display region DA-M. Alternatively, without being limited thereto, the display region of the display device DD may include a sub-display region bent while extending (or extending in a bent or curved shape) from at least one side among the four sides of the main display region DA-M. That is, the display device DD according to an embodiment may include only some of the four sub-display regions DA-S1, DA-S2, DA-S3, and DA-S4.

Referring to FIG. 2, the display device DD may include a window member WN and a display member DS. The display device DD according to an embodiment may further include a circuit board that is electrically connected to the display member DS and that transmits a drive signal.

The window member WN may be disposed on the display member DS. The window member WN may be coupled with the display member DS through a process such as lamination. The window member WN may cover the display member DS and may protect the display member DS from external impacts and scratches.

The window member WN may include an optically clear insulating material. In an embodiment, for example, the window member WN may include a base film containing or including glass or a synthetic resin. The window member WN may have a single-layer structure or a multi-layer structure. In an embodiment, for example, the window member WN having a multi-layer structure may include synthetic resin films coupled by an adhesive, or may include a glass film and a synthetic resin film coupled by an adhesive. The window member WN may further include a functional layer, such as an anti-fingerprint layer, a phase control layer or a hard coating layer, which is disposed on the base film.

The window member WN may include a transmissive region, and the transmissive region of the window member WN may correspond to the above-described display region of the display device DD. The transmissive region of the window member WN may transmit an image output from the display member DS, and a user may visually recognize the image from outside the display device DD. The transmissive region of the window member WN may include a main transmissive surface TA-M and first to fourth side transmissive surfaces TA-S1, TA-S2, TA-S3, and TA-S4.

The main transmissive surface TA-M may correspond to the main display region DA-M. The main transmissive surface TA-M may be on a plane substantially parallel to the plane defined by the first direction DR1 and the second direction DR2.

Each of the first to fourth side transmissive surfaces TA-S1, TA-S2, TA-S3, and TA-S4 may be bent from the main transmissive surface TA-M with a curvature. Each of the first to fourth side transmissive surfaces TA-S1, TA-S2, TA-S3, and TA-S4 may include a curved surface extending from the main transmissive surface TA-M. The first to fourth side transmissive surfaces TA-S1, TA-S2, TA-S3, and TA-S4 may correspond to the above-described first to fourth sub-display regions DA-S1, DA-S2, DA-S3, and DA-S4, respectively.

The main transmissive surface TA-M and the first to fourth side transmissive surfaces TA-S1, TA-S2, TA-S3, and TA-S4 may be adjacent to each other and may implement a continuous transmissive region. The first to fourth side transmissive surfaces TA-S1, TA-S2, TA-S3, and TA-S4 may be connected with each other and may surround the main transmissive surface TA-M. The first side transmissive surface TA-S1 and the third side transmissive surface TA-53 may extend in the first direction DR1, and the second side transmissive surface TA-S2 and the fourth side transmissive surface TA-S4 may extend in the second direction DR2.

The display member DS may be disposed under the window member WN and may be attached to the window member WN. The display member DS may display the image in response to an electrical signal. In some embodiments, the display member DS may transmit and receive information about the external input. The display member DS may include an active region AA-DA and a peripheral region AA-NDA adjacent to the active region AA-DA.

The active region AA-DA may be a region that is activated in response to the electrical signal and that displays the image. In some embodiments, the active region AA-DA may be a region where the image is displayed and the external input is sensed at the same time. However, this is illustrative. Alternatively, a region where the image is displayed and a region where the external input is sensed may be separated from each other in the active region AA-DA, and the disclosure is not limited to any one embodiment.

The display member DS may include pixels PX disposed in the active region AA-DA. The arrangement of the pixels PX in the active region AA-DA may be diversely designed and is not limited to any one embodiment. Each of the pixels PX may include a light emitting element and a pixel drive circuit connected with the light emitting element and constituted by transistors (e.g., a switching transistor and a drive transistor) and at least one capacitor. The pixels PX may output light in response to electrical signals applied to the pixels PX and may display the image through the active region AA-DA.

The active region AA-DA may overlap the transmissive region of the window member WN. Accordingly, the image output from the active region AA-DA may be visible to the user through the transmissive region of the window member WN.

The peripheral region AA-NDA may be adjacent to the active region AA-DA. In an embodiment, for example, the peripheral region AA-NDA may surround the active region AA-DA. Alternatively, without being limited thereto, the peripheral region AA-NDA may be defined in another shape selected from various other shapes. A drive circuit, a drive line, and a pad for transmitting a signal to drive the active region AA-DA may be disposed in the peripheral region AA-NDA.

The display member DS may include a flat portion FA and at least one bending portion. FIG. 2 illustrates an embodiment in which the display member DS includes first to fourth bending portions BA-S1, BA-S2, BA-S3, and BA-S4.

The flat portion FA may be on a plane substantially parallel to the plane defined by the first direction DR1 and the second direction DR2. The flat portion FA may overlap the main transmissive surface TA-M. A front surface of the flat portion FA may be provided as the active region AA-DA. Alternatively, without being limited thereto, part of the flat portion FA may be provided as the peripheral region AA-NDA.

The first to fourth bending portions BA-S1, BA-S2, BA-S3, and BA-S4 may be bent while extending from the flat portion FA. Each of the first to fourth bending portions BA-S1, BA-S2, BA-S3, and BA-S4 may include a curved surface having a curvature while extending from the flat portion FA. The first to fourth bending portions BA-S1, BA-S2, BA-S3, and BA-S4 may overlap the first to fourth side transmissive surfaces TA-S1, TA-S2, TA-S3, and TA-S4, respectively.

The flat portion FA and the first to fourth bending portions BA-S1, BA-S2, BA-S3, and BA-S4 may be adjacent to each other and may implement the continuous active region AA-DA. Part of each of the first to fourth bending portions BA-S1, BA-S2, BA-S3, and BA-S4 may be provided as part of the active region AA-DA. In such an embodiment, the display member DS may output the image through at least parts of the first to fourth bending portions BA-S1, BA-S2, BA-S3, and BA-S4. In some embodiments, at least some of the first to fourth bending portions BA-S1, BA-S2, BA-S3, and BA-S4 may be provided as the peripheral region AA-NDA.

The first to fourth bending portions BA-S1, BA-S2, BA-S3, and BA-S4 may be connected with each other and may surround the flat portion FA. Each of the first bending portion BA-S1 and the third bending portion BA-S3 may extend from the flat portion FA in a direction parallel to the second direction DR2. Each of the first bending portion BA-S1 and the third bending portion BA-S3 may extend along the first direction DR1 (or along a side of the flat portion FA in the first direction DR1) and may include a curved surface bent about a bending axis parallel to the first direction DR1. Each of the second bending portion BA-S2 and the fourth bending portion BA-S4 may extend from the flat portion FA in a direction parallel to the first direction DR1. Each of the second bending portion BA-S2 and the fourth bending portion BA-S4 may extend along the second direction DR2 (or along a side of the flat portion FA in the second direction DR2) and may include a curved surface bent about a bending axis parallel to the second direction DR2.

In a process of attaching the display member DS and the window member WN to each other, the flat portion FA of the display member DS may be attached to the main transmissive surface TA-M. The first to fourth bending portions BA-S1, BA-S2, BA-S3, and BA-S4 of the display member DS may be attached to the first to fourth side transmissive surfaces TA-S1, TA-S2, TA-S3, and TA-S4, respectively.

The first bending portion BA-S1 corresponding to a lower end of the display member DS may further include a protruding portion PA provided as the peripheral region AA-NDA. In an embodiment, the protruding portion PA may be bent about a bending axis parallel to the first direction DR1 toward a rear surface of the display member DS that corresponds to the flat portion FA. In such an embodiment, the protruding portion PA may overlap the flat portion FA in a plan view. The protruding portion PA may be a region to which the circuit board of the display device DD is connected or on which a drive IC is mounted. Alternatively, without being limited thereto, the protruding portion PA may be omitted.

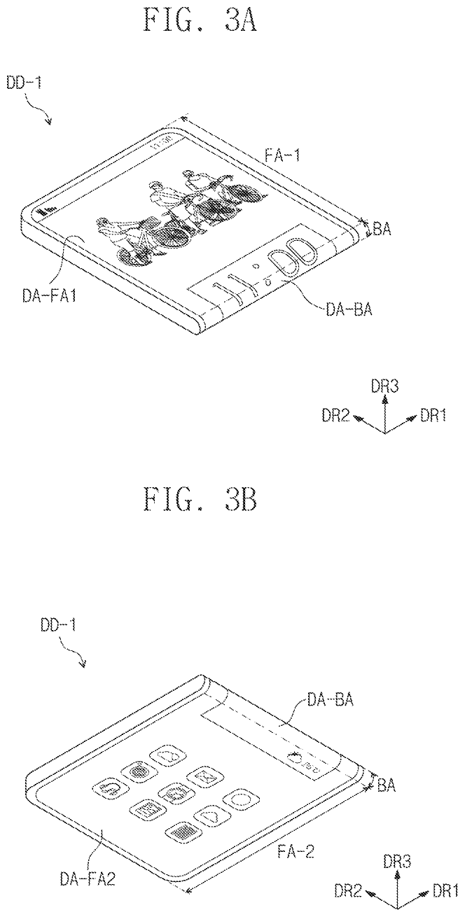

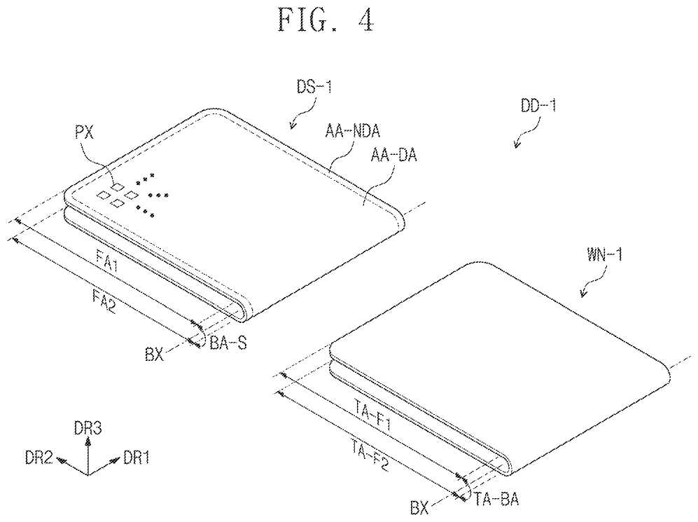

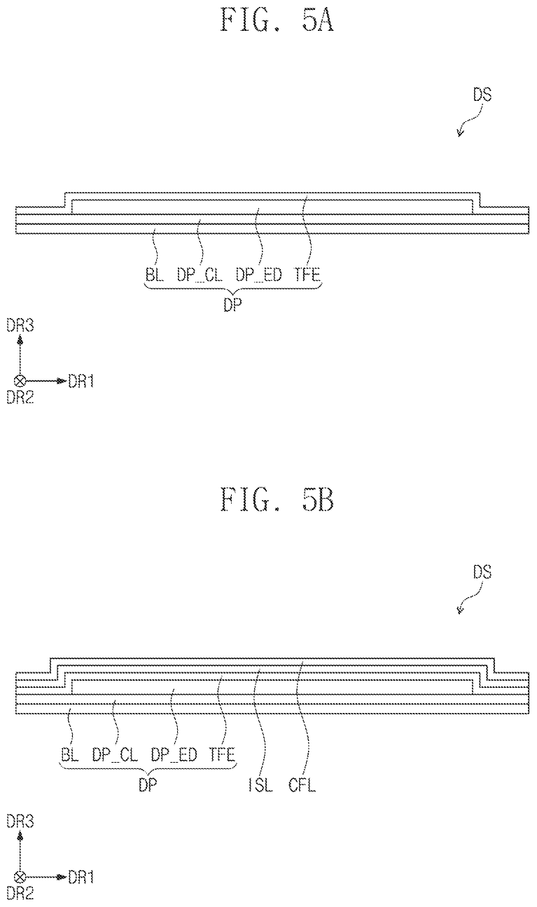

FIGS. 3A and 3B are perspective views of a display device DD-1 according to an embodiment of the disclosure. FIGS. 3A and 3B are perspective views of the display device DD-1 as viewed in different directions. FIG. 4 is an exploded perspective view of the display device DD-1 illustrated in FIG. 3A.

Referring to FIGS. 3A and 3B, an embodiment of the display device DD-1 may include first and second non-bending regions FA-1 and FA-2 and a bending region BA. The bending region BA may be disposed between the first non-bending region FA-1 and the second non-bending region FA-2 and may be bent with a curvature. The first non-bending region FA-1 may extend in the second direction DR2 from one side of the bending region BA that is parallel to the first direction DR1, and the second non-bending region FA-2 may extend in the second direction DR2 from an opposite side of the bending region BA that is parallel to the first direction DR1. The first non-bending region FA-1 and the second non-bending region FA-2 may overlap each other in the third direction DR3.

A display region that is activated in response to an electrical signal and that displays an image may be defined on the display device DD-1. The display region of the display device DD-1 may include a first flat display region DA-FA1, a second flat display region DA-FA2, and a bending display region DA-BA. The first flat display region DA-FA1 may be disposed in the first non-bending region FA-1, and the second flat display region DA-FA2 may be disposed in the second non-bending region FA-2. The bending display region DA-BA may be disposed in the bending region BA.

The first flat display region DA-FA1 and the second flat display region DA-FA2 may be on a plane substantially parallel to the plane defined by the first direction DR1 and the second direction DR2. A direction in which an image is displayed through the first flat display region DA-FA1 may be opposite a direction in which an image is displayed through the second flat display region DA-FA2. The bending display region DA-BA may include a curved surface bent about a bending axis parallel to the first direction DR1.

The first flat display region DA-FA1, the bending display region DA-BA, and the second flat display region DA-FA2 may be adjacent to each other and may implement a continuous display region. The first flat display region DA-FA1, the bending display region DA-BA, and the second flat display region DA-FA2 may be independently controlled and may display different images from each other. Alternatively, the first flat display region DA-FA1, the bending display region DA-BA, and the second flat display region DA-FA2 may display an integrally connected image or respectively display parts of a single image.

Referring to FIGS. 3A, 3B, and 4, the display device DD-1 may include a window member WN-1 and a display member DS-1. The display device DD-1 according to an embodiment may further include a circuit board that is electrically connected to the display member DS-1 and transmits a drive signal.

The window member WN-1 may be disposed on the display member DS-1 and may be coupled with the display member DS-1 through a process such as lamination. The window member WN-1 may cover the display member DS-1 and may protect the display member DS-1 from external impacts and scratches.

The window member WN-1 may include an optically clear insulating material. In an embodiment, for example, the window member WN-1 may include glass or a synthetic resin. The window member WN-1 of FIG. 4 is substantially the same as the window member WN of FIG. 2 except for the shape thereof, and description about a material constituting the window member or a stacked structure thereof described above may be applied to the window member WN of FIG. 2.

The window member WN-1 may include a transmissive region, and the transmissive region of the window member WN-1 may include a first flat transmissive surface TA-F1, a bending transmissive surface TA-BA, and a second flat transmissive surface TA-F2. The transmissive region of the window member WN-1 may transmit the image output from the display member DS-1.

The first flat transmissive surface TA-F1 may correspond to the first flat display region DA-FA1, and the second flat transmissive surface TA-F2 may correspond to the second flat display region DA-FA2. Each of the first flat transmissive surface TA-F1 and the second flat transmissive surface TA-F2 may be on a plane substantially parallel to the plane defined by the first direction DR1 and the second direction DR2.

The bending transmissive surface TA-BA may be disposed between the first flat transmissive surface TA-F1 and the second flat transmissive surface TA-F2 and may be connected to (or extend from) the first flat transmissive surface TA-F1 and the second flat transmissive surface TA-F2. The first flat transmissive surface TA-F1, the bending transmissive surface TA-BA, and the second flat transmissive surface TA-F2 may be adjacent to each other and may implement a continuous transmissive region. The bending display surface TA-BA may include a curved surface bent about a bending axis BX parallel to the first direction DR1. The bending transmissive surface TA-BA may correspond to the bending display region DA-BA.

The display member DS-1 may be disposed under the window member WN-1 and may be attached to the window member WN-1. The display member DS-1 may display the image in response to an electrical signal and may sense an external input. The display member DS-1 may include an active region AA-DA and a peripheral region AA-NDA adjacent to the active region AA-DA. The display member DS-1 may include pixels PX disposed in the active region AA-DA. The display member DS-1 of FIG. 4 is substantially the same as the display member DS of FIG. 2 except for the shape thereof, and the above description may be identically applied to the active region AA-DA, the peripheral region AA-NDA, and the pixels PX.

The display member DS-1 may include a first flat portion FA1, a second flat portion FA2, and a bending portion BA-S. The active region AA-DA may be defined in the first flat portion FA1, the second flat portion FA2, and the bending portion BA-S. The active region AA-DA defined in the first flat portion FA1, the second flat portion FA2, and the bending portion BA-S may be implemented as an integrated region or integrally formed as a single unitary and indivisible part.

Each of the first flat portion FA1 and the second flat portion FA2 may be on a plane substantially parallel to the plane defined by the first direction DR1 and the second direction DR2. A portion of the active region AA-DA that corresponds to the first flat portion FA1 and a portion of the active region AA-DA that corresponds to the second flat portion FA2 may output images in opposite directions. The first flat portion FA1 may overlap the first flat transmissive surface TA-F1, and the second flat portion FA2 may overlap the second flat transmissive surface TA-F2. Part of the first flat portion FA1 and part of the second flat portion FA2 may be provided as the peripheral region AA-NDA.

The bending portion BA-S may be integrally connected to the first flat portion FA1 and the second flat portion FA2 and may include a curved surface. The bending portion BA-S may extend along the first direction DR1 and may be a portion bent about the bending axis BX parallel to the first direction DR1. A portion of the active region AA-DA may be defined in the bending portion BA-S. At least part of the bending portion BA-S may be provided as the peripheral region AA-NDA. The bending portion BA-S may overlap the bending transmissive surface TA-BA.

In a process of attaching the display member DS-1 and the window member WN-1 to each other, the first flat portion FA1 of the display member DS-1 may be attached to the first flat transmissive surface TA-F1, and the second flat portion FA2 of the display member DS-1 may be attached to the second flat transmissive surface TA-F2. The bending portion BA-S of the display member DS-1 may be attached to the bending transmissive surface TA-BA.

FIGS. 5A and 5B are sectional views of the display member DS according to an embodiment of the disclosure. Description of the display member DS of FIGS. 5A and 5B may be applied to the display member DS-1 of FIG. 4.

Referring to FIG. 5A, the display member DS may include a display panel DP. The display panel DP according to an embodiment may be an emissive display panel and is not particularly limited thereto. In an embodiment, for example, the display panel DP may be an organic light emitting display panel, an inorganic light emitting display panel, or a quantum-dot light emitting display panel. An emissive layer of the organic light emitting display panel may include an organic light emitting material, and an emissive layer of the inorganic light emitting display panel may include an inorganic light emitting material. An emissive layer of the quantum-dot light emitting display panel may include quantum dots and quantum rods. Hereinafter, for convenience of description, embodiments where the display panel DP is an organic light emitting display panel will be described.

In an embodiment, the display panel DP may include a base layer BL, a circuit layer DP_CL, a display element layer DP_ED, and an encapsulation layer TFE.

The base layer BL may provide a base surface on which the circuit layer DP_CL is disposed. The base layer BL may be a rigid substrate, or a flexible substrate that can be bent, folded, or rolled. In an embodiment, for example, the base layer BL may be a glass substrate, a metal substrate, a polymer substrate, or the like.

The base layer BL may have a multi-layer structure. In an embodiment, for example, the base layer BL may include synthetic resin layers and at least one inorganic layer disposed between the synthetic resin layers. The synthetic resin layers of the base layer BL may include at least one selected from an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, and a polyimide-based resin. However, the material of the base layer BL is not limited thereto.

The circuit layer DP_CL may be disposed on the base layer BL. The circuit layer DP_CL may include an insulating pattern, a semiconductor pattern, and a conductive pattern that form a pixel drive circuit of a pixel PX (refer to FIG. 2), a drive line, and a pad. In a manufacturing process of the display panel DP, the circuit layer DP_CL may be formed by forming an insulating layer, a semiconductor layer, and a conductive layer on the base layer BL through coating or deposition and thereafter patterning the insulating layer, the semiconductor layer, and the conductive layer subject by performing photolithography a plurality of times.

The display element layer DP_ED may be disposed on the circuit layer DP_CL. The display element layer DP_ED may include light emitting elements constituting the pixels PX (refer to FIG. 2). The light emitting elements may be electrically connected with the pixel drive circuit of the circuit layer DP_CL. The light emitting elements may include an organic light emitting element, an inorganic light emitting element, a micro light-emitting diode (LED), or a nano LED and are not limited to any one as long as the amount of light is able to be controlled depending on an electrical signal.

The encapsulation layer TFE may be disposed on the display element layer DP_ED and may seal the display element layer DP_ED. The encapsulation layer TFE may include at least one thin film for improving the optical efficiency of the display element layer DP_ED or protecting the display element layer DP_ED. In an embodiment, for example, the encapsulation layer TFE may include at least one selected from an inorganic film and an organic film. The inorganic film of the encapsulation layer TFE may protect the display element layer DP_ED from moisture/oxygen. The organic film of the encapsulation layer TFE may protect the display element layer DP_ED from foreign matter such as dust particles.

The inorganic film of the encapsulation layer TFE may include at least one selected from aluminum oxide, titanium oxide, silicon oxide, silicon nitride, silicon oxy-nitride, zirconium oxide, and hafnium oxide. The organic film of the encapsulation layer TFE may include an acrylate-based resin. However, the material of the encapsulation layer TFE is not limited thereto.

Referring to FIG. 5B, the display member DS according to an embodiment may further include an input sensing layer ISL and an anti-reflection layer CFL. The input sensing layer ISL and the anti-reflection layer CFL may be disposed on the display panel DP in the third direction DR3.

The input sensing layer ISL may be disposed on the display panel DP. The input sensing layer ISL may be directly disposed on the display panel DP. In such an embodiment, where the input sensing layer ISL is directly disposed on the display panel DP, the input sensing layer ISL may be formed on the display panel DP through a continuous process and the input sensing layer ISL and the display panel DP are coupled without a separate adhesive layer. Alternatively, without being limited thereto, the input sensing layer ISL may be coupled with the display panel DP through a separate adhesive layer.

The input sensing layer ISL may obtain coordinate information of an external input applied from outside the display device DD (refer to FIG. 1). The external input may include various forms of inputs such as force, pressure, temperature, light, and the like. In an embodiment, for example, the external input may be a user's hand or an electronic pen in contact with the display device DD (refer to FIG. 1), or may include an input such as hovering applied in proximity to the display device DD (refer to FIG. 1).

The input sensing layer ISL may be driven in various ways to sense the external input applied from outside the display device DD (refer to FIG. 1). In an embodiment, for example, the input sensing layer ISL may be operated by a capacitive sensing method, a resistance sensing method, an infrared sensing method, a sound-wave sensing method, or a pressure sensing method and is not limited to any one as long as an external input is able to be sensed.

The anti-reflection layer CFL may be disposed on the input sensor layer ISL. In an embodiment, for example, the anti-reflection layer CFL may be directly disposed on the input sensing layer ISL. The anti-reflection layer CFL may be formed on a base surface provided by the input sensing layer ISL. Alternatively, without being limited thereto, the anti-reflection layer CFL may be coupled with the input sensing layer ISL through an adhesive layer. In an embodiment, as shown in FIG. 5B, the input sensing layer ISL may be disposed under the anti-reflection layer CFL, but the stacking sequence of the input sensing layer ISL and the anti-reflection layer CFL is not limited thereto.

The anti-reflection layer CFL may decrease the reflectivity of an external light incident from above the display device DD (refer to FIG. 1). The anti-reflection layer CFL may include various embodiments that reduce the reflectivity of the external light.

The anti-reflection layer CFL according to an embodiment may include a phase retarder and a polarizer. The phase retarder may include a X/2 phase retarder and/or a X/4 phase retarder. The phase retarder and the polarizer may be of a film type or a liquid crystal coating type. The film type polarizer may include a stretchable synthetic resin film, and the liquid crystal coating type polarizer may include liquid crystals arranged in a predetermined arrangement. Alternatively, without being limited thereto, the phase retarder and the polarizer may be implemented with one polarizer film. The anti-reflection layer CFL may further include a protective film disposed on or under the polarizer film.

The anti-reflection layer CFL according to an embodiment may include a destructive interference structure. In an embodiment, for example, the destructive interference structure may include a first reflective layer and a second reflective layer that are disposed on different layers. First reflected light reflected by the first reflective layer and second reflected light reflected by the second reflective layer may destructively interfere with each other, and thus the anti-reflection layer CFL may decrease the reflectivity of the external light.

The anti-reflection layer CFL according to an embodiment may include color filters. The color filters may be disposed to correspond to the arrangement and light emission colors of the pixels PX (refer to FIG. 2) included in the display panel DP. The anti-reflection layer CFL may filter the external light incident from above the display device DD (refer to FIG. 1) in colors corresponding to the light emission colors of the pixels PX (refer to FIG. 2). The anti-reflection layer CFL may further include a black matrix adjacent to the color filters.

In an embodiment, the display member DS may further include a lower member disposed under the display panel DP. The lower member may include at least one layer that protects the display panel DP. In an embodiment, for example, the lower member may include a light blocking layer, a heat radiating layer, or a cushion layer.

The light blocking layer may prevent components on a rear surface of the display panel DP from being visible from the outside. The light blocking layer may include a light blocking material and may prevent reflected light from being delivered to the outside. In an embodiment, for example, the light blocking layer may include a binder and pigment particles such as carbon black dispersed therein.

The heat radiating layer may protect the display panel DP by radiating heat generated from elements disposed under the display panel DP. The heat radiating layer may include a material (e.g., stainless steel, graphite, copper (Cu), or aluminum (Al)) having high heat dissipation characteristics. The heat radiating layer may electromagnetic wave shielding or absorbing characteristics in addition to the heat dissipation characteristics and may block noise from being generated in the display panel DP.

The cushion layer may absorb an external impact applied to the rear surface of the display panel DP. The cushion layer may include a material having elasticity. In an embodiment, for example, the cushion layer may include synthetic resin foam having a porous structure. A plurality of pores dispersed in the cushion layer may absorb the external impact, and thus the cushion layer may improve the impact resistance of the display member DS.

Portions bent with predetermined curvatures, such as the first to fourth bending portions BA-S1, BA-S2, BA-S3, and BA-S4 of FIG. 2 or the bending portion BA-S of FIG. 4, may have relatively weak durability due to stress caused by bending, and the display member DS or DS-1 may be damaged in a process of attaching the display member DS or DS-1 (refer to FIG. 2 or 4) and the window member WN or WN-1 (refer to FIG. 2 or 4). Furthermore, compared to the flat portion, the bending portion of the display member DS or DS-1 having a predetermined curvature may fail to sufficiently adhere to the window member WN or WN-1.

A display module according to an embodiment of the disclosure may include a guide film that supports the display member DS or DS-1 and is provided an opening defined therein. That is, in such an embodiment, an opening is defined in the guide film. Accordingly, the display member DS or DS-1 may be protected in a process of attaching the display member DS or DS-1 and the window member WN or WN-1 to each other, and the display member DS or DS-1 and the window member WN or WN-1 may be attached to each other without a defect. Thus, process reliability may be improved. The display module including the guide film will hereinafter be described below in detail.

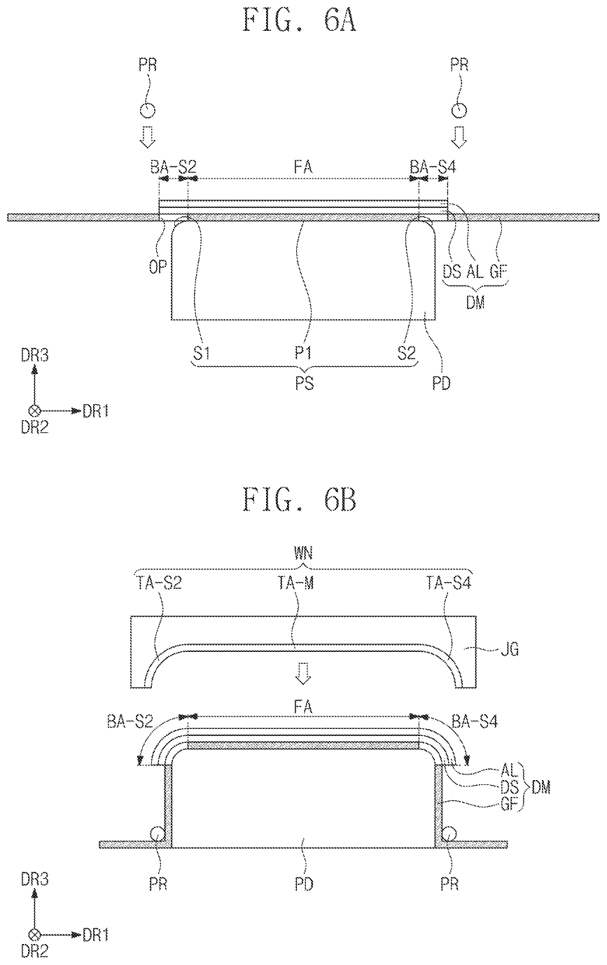

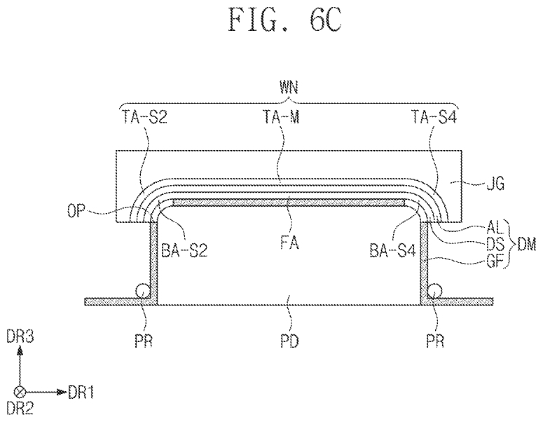

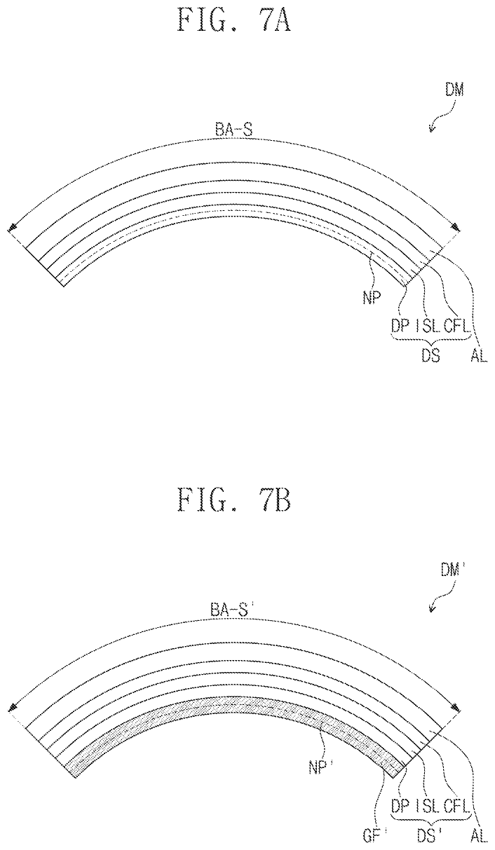

FIGS. 6A to 6C are sectional views illustrating a method of attaching a display module and a window member to each other according to an embodiment of the disclosure. processes illustrated in FIGS. 6A to 6C may correspond to a process of manufacturing the display device DD of FIG. 2.

Referring to FIGS. 6A to 6C, the process of attaching the display module DM and the window member WN to each other may include a process of providing the display module DM on a pressure pad PD. In such embodiment, the display module DM may correspond to the display member DS having a guide film GF attached to the rear surface thereof.

The display module DM may include the display member DS, the guide film GF, and an adhesive layer AL. FIG. 6A illustrates a section of the display member DS that corresponds to the flat portion FA, the second bending portion BA-S2, and the fourth bending portion BA-S4. The guide film GF may be disposed on the rear surface of the display member DS. The guide film GF may be attached to the rear surface of the display member D S. The adhesive layer AL may be disposed on the upper surface of the display member DS. Alternatively, without being limited thereto, the adhesive layer AL may be disposed on a lower surface of the window member WN that is to be provided on the display module DM.

The adhesive layer AL may include a general adhesive or sticky substance. In an embodiment, for example, the adhesive layer AL may include a transparent adhesive such as a pressure sensitive adhesive (PSA) film, an optically clear adhesive (OCA) film, or an optically clear resin (OCR).

Openings OP may be defined or formed through the guide film GF. The openings OP of the guide film GF may be defined to correspond to regions in which bending portions of the display member DS are to be formed. In an embodiment, for example, referring to FIG. 6A, the openings OP may overlap the second bending portion BA-S2 and the fourth bending portion BA-S4.

The pressure pad PD may include a material that is easily deformed by pressure. In an embodiment, for example, the pressure pad PD may include an elastic material such as silicone.

The pressure pad PD may include a pressure surface PS. The pressure surface PS of the pressure pad PD may include a first surface P1 and first and second side surfaces S1 and S2 bent from the first surface P1. Each of the first side surface S1 and the second side surface S2 may include a curved surface extending from the first surface P1. The first surface P1 of the pressure pad PD may overlap the flat portion FA of the display member DS and may support the flat portion FA. The first side surface S1 of the pressure pad PD may overlap the second bending portion BA-S2, and the second side surface S2 of the pressure pad PD may overlap the fourth bending portion BA-S4.

The display module DM may be fixed to a clamp and may be provided on the pressure pad PD. In an embodiment, for example, the clamp may clamp the guide film GF of the display module DM. in such an embodiment, the display member DS attached to the guide film GF may be indirectly fixed through the guide film GF without being directly fixed to the clamp. Accordingly, the display member DS may be effectively prevented from being damaged by the clamp.

Pressing parts PR may be provided on the display module DM. The pressing parts PR may have a rod shape extending in the second direction DR2. The pressing parts PR may fix the guide film GF such that the guide film GF is brought into close contact with the pressure pad PD in a process in which the guide film GF is brought into contact with the pressure pad PD to correspond to the shape of the pressure pad PD.

In a process in which the pressure pad PD presses the display module DM in the third direction DR3, the guide film GF may be brought into close contact with the pressure pad PD. The second bending portion BA-S2 and the fourth bending portion BA-S4 of the display member DS may be bent to correspond to the shape of the pressure pad PD. The adhesive layer AL disposed on the display member DS may have a shape corresponding to the shape of the display member DS.

The process of attaching the display module DM and the window member WN to each other may include a process of providing a jig JG having the window member WN disposed thereon on the display module DM. The window member WN may be fixedly disposed in a receiving recess defined or formed in the jig JG. The window member WN may have a shape corresponding to the shape of the receiving recess of the jig JG. The window member WN may include the main transmissive surface TA-M, the second side transmissive surface TA-S2, and the fourth side transmissive surface TA-S4 that overlap the flat portion FA, the second bending portion BA-S2, and the fourth bending portion BA-S4 of the display member DS, respectively.

The window member WN and the display member DS may be attached to each other through the adhesive layer AL. The main transmissive surface TA-M of the window member WN may be attached to the flat portion FA of the display member DS. The second side transmissive surface TA-S2 and the fourth side transmissive surface TA-S4 of the window member WN, which include a curved surface, may be attached to the second bending portion BA-S2 and the fourth bending portion BA-S4 of the display member DS, respectively.

In the process of providing the jig JG having the window member WN fixed thereto on the display module DM, a predetermined gap may be desired between the display member DS and the window member WN to correspond to the bending portions of the display member DS. In a case in which there is no gap between the display member DS and the window member WN, the window member WN may make contact with the bending portions of the display member DS before attached to the display member DS, such that the window member WN and the display member DS may be incompletely attached to each other, or the display member DS may be caught due to stress applied thereto.

In an embodiment, the guide film GF is provided with the openings OP overlapping the bending portions of the display member DS, such that a gap desired for the attachment process may be provided or formed between the display member DS and the window member WN. Accordingly, a defect may be effectively prevented in the process of attaching the display member DS and the window member WN, and process reliability may be improved.

In such an embodiment, since the guide film GF is provided with the openings OP overlapping the bending portions of the display member DS, a modulus of the guide film GF that corresponds to the bending portions of the display member DS may be decreased. In such an embodiment, in a process in which the bending portions of the display member DS are bent, a neutral plane may be defined in the display member DS in the display module DM in which the guide film GF, the display member DS, and the adhesive layer AL are stacked. Accordingly, components in the bending portions of the display member DS may be effectively prevented from being damaged by stress caused by bending. Detailed description thereabout will be given below with reference to FIGS. 7A and 7B.

In an embodiment, after the window member WN and the display member DS of the display module DM are attached to each other, the display module DM to which the window member WN is attached may be spaced apart from the pressure pad PD. After the window member WN and the display member DS are coupled to each other, the guide film GF may be removed from the display member DS. Accordingly, the finally manufactured display device DD (refer to FIG. 1) may include the display member DS from which the guide film GF is removed. Thus, the guide film GF provided with the openings OP may effectively prevent a defect in the attachment process of the display member DS and the window member WN without affecting the manufactured display member DS.

FIG. 7A is a sectional view of a display module DM according to an embodiment of the disclosure. FIG. 7B is a sectional view of a display module DM′ according to a comparative example. FIG. 7A illustrates a section corresponding to the bending portion BA-S of the display module DM according to an embodiment, and FIG. 7B illustrates a section corresponding to a bending portion BA-S′ of the display module DM′ according to the comparative example.

Referring to FIG. 7A, the guide film GF (refer to FIG. 6C) included in the display module DM according to the embodiment may be provided with the opening OP (refer to FIG. 6C) corresponding to the bending portion BA-S of the display member DS, and thus at least part of the bending portion BA-S may not overlap the guide film GF (refer to FIG. 6C).

In an embodiment, as described above, the display member DS may include the display panel DP, the input sensing layer ISL, and the anti-reflection layer CFL. As the bending portion BA-S is bent, the display panel DP, the input sensing layer ISL, and the anti-reflection layer CFL may be bent with a curvature. In addition, the adhesive layer AL disposed on the display member DS may also be bent together with the bending portion BA-S.

When the display module DM having a multi-layer structure is bent, a neutral plane NP where tensile stress and compressive stress are in equilibrium on the section may be defined therein. In the bending portion BA-S, compressive stress applied to the display module DM may be increased as being toward the center of curvature from the neutral plane NP, and tensile stress applied to the display module DM may be increased as being away from the center of curvature from the neutral plane NP.

The position of the neutral plane NP may be affected by the materials, structures, thicknesses, moduli, and Poisson's ratios of stacked components. Depending on the position where the neutral plane NP is formed in the display module DM, tensile stress may be applied to some of the components, and compressive stress may be applied to the other components during bending.

In an embodiment, since the guide film GF (refer to FIG. 6C) does not overlap at least part of the bending portion BA-S due to the opening OP (refer to FIG. 6C) corresponding thereto, the neutral plane NP defined in the display member DS in the bending portion BA-S may not be affected by the guide film GF. In such an embodiment, for example, the neutral plane NP of the bending portion BA-S may be defined in the display panel DP. In such an embodiment, since the neutral plane NP is formed in the display member DS, the magnitude of tensile stress applied to the bending portion BA-S of the display member DS may be decreased, and damage to the display member DS by the tensile stress may be effectively prevented.

However, referring to FIG. 7B, a guide film GF′ included in the display module DM′ according to the comparative example may overlap a bending portion BA-S′ of a display member DS′. That is, the guide film GF′ according to the comparative example may be attached to the rear surface of the bending portion BA-S′.

Since the guide film GF′ according to the comparative example overlaps the bending portion BA-S′, a neutral plane NP′ may be defined in the guide film GF′ in the bending portion BA-S′. Since the neutral plane NP′ is formed in the guide film GF′, the display member DS' disposed on the guide film GF′ is spaced away from the neutral plane NP′ and is subjected to larger tensile stress than the display member DS according to the embodiment of the disclosure. As the magnitude of tensile stress acting in the display member DS' is increased, components in the bending portion BA-S′ according to the comparative example may be damaged.

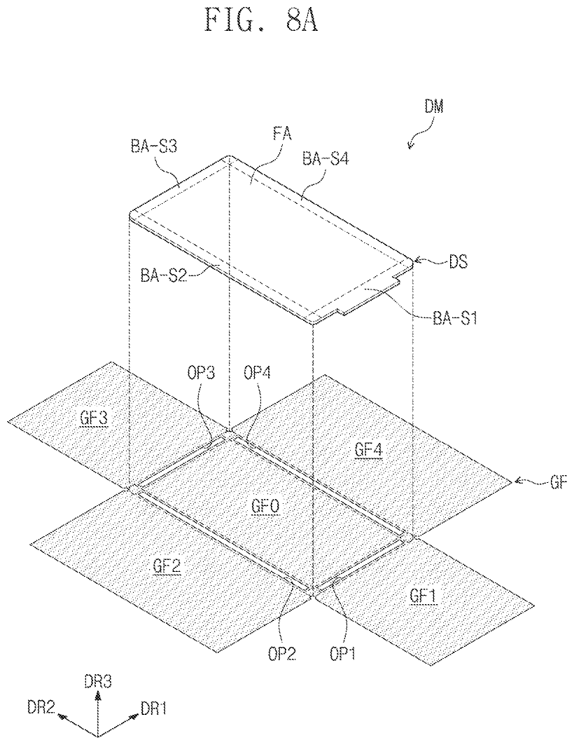

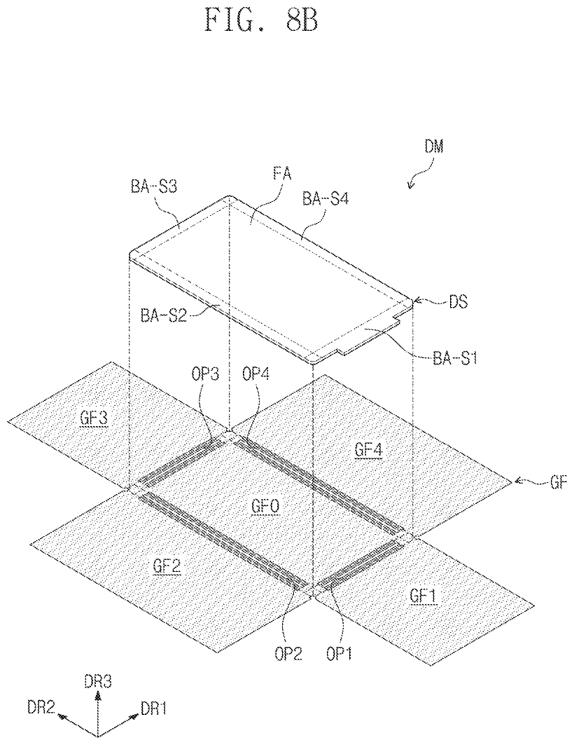

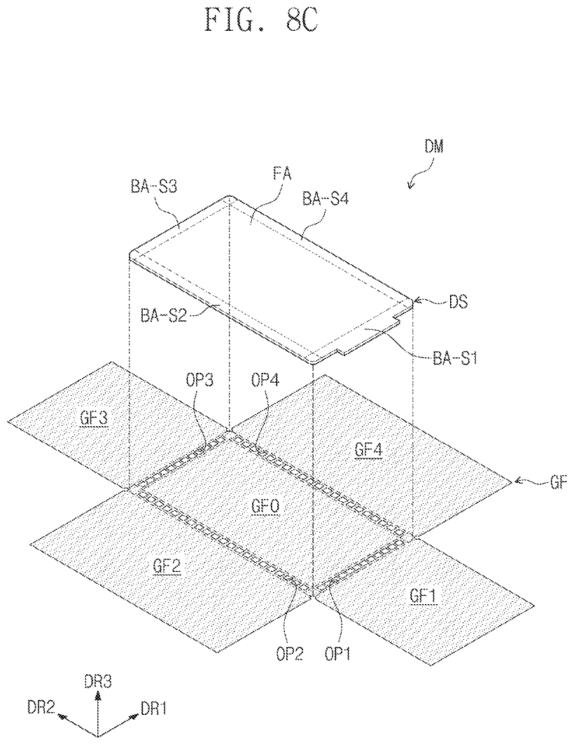

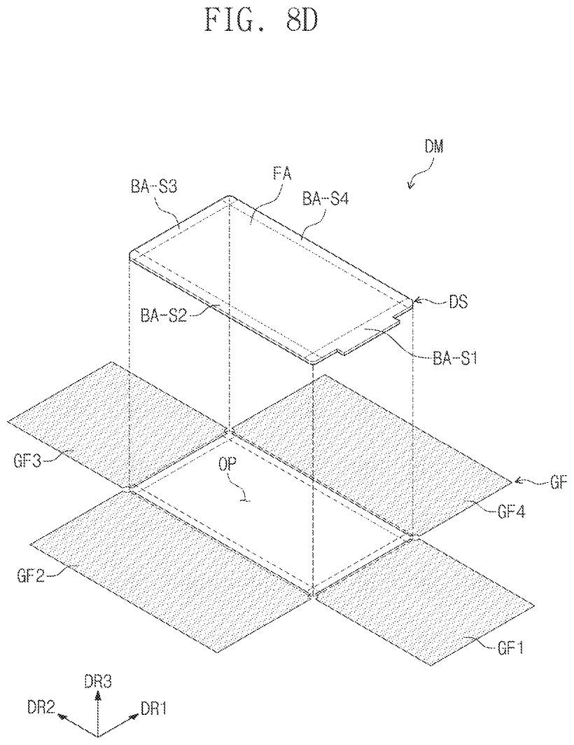

FIGS. 8A to 8D are perspective views of a display module DM according to embodiments of the disclosure. FIGS. 8A to 8D illustrate various embodiments where an opening is defined or formed in the guide film GF.

The display member DS included in the display module DM of FIGS. 8A to 8D may correspond to the display member DS of FIG. 2, and the above description may be identically applied thereto.

Referring to FIG. 8A, in an embodiment, the display module DM may include the display member DS and the guide film GF disposed on the rear surface of the display member DS. The guide film GF may include extended portions outward of edges of the display member DS in a plan view. The guide film GF may include a first portion GF0 overlapping the display member DS and first to fourth extended portions GF1, GF2, GF3, and GF4 extending from the first portion GF0.

The first extended portion GF1 may extend in a direction parallel to the second direction DR2 from a first side of the first portion GF0 that is parallel to the first direction DR1. The third extended portion GF3 may extend in a direction parallel to the second direction DR2 from a second side of the first portion GF0 that is parallel to the first direction DR1 and faces the first side. The first extended portion GF1 and the third extended portion GF3 may be spaced apart from each other in the second direction DR2 with the first portion GF0 therebetween.

The second extended portion GF2 may extend in a direction parallel to the first direction DR1 from a third side of the first portion GF0 that is parallel to the second direction DR2. The fourth extended portion GF4 may extend in a direction parallel to the first direction DR1 from a fourth side of the first portion GF0 that is parallel to the second direction DR2 and faces the third side. The second extended portion GF2 and the fourth extended portion GF4 may be spaced apart from each other in the first direction DR1 with the first portion GF0 therebetween.

The first portion GF0 of the guide film GF may overlap the flat portion FA and the first to fourth bending portions BA-S1, BA-S2, BA-S3, and BA-S4 of the display member DS. First to fourth openings OP1, OP2, OP3, and OP4 overlapping the first to fourth bending portions BA-S1, BA-S2, BA-S3, and BA-S4, respectively, may be defined or formed in the first portion GF0 of the guide film GF.

In an embodiment, the first opening OP1 may extend in the first direction DR1 and may overlap the first bending portion BA-S1. The second opening OP2 may extend in the second direction DR2 and may overlap the second bending portion BA-S2. The third opening OP3 may extend in the first direction DR1 and may overlap the third bending portion BA-S3. The fourth opening OP4 may extend in the second direction DR2 and may overlap the fourth bending portion BA-S4.

The area of each of the first to fourth openings OP1, OP2, OP3, and OP4 may be about 50% or greater of the area of a corresponding bending portion among the first to fourth bending portions BA-S1, BA-S2, BA-S3, and BA-S4. In an embodiment, for example, the area of the first opening OP1 may be 50% or more of the area of the first bending portion BA-S1.

The first to fourth openings OP1, OP2, OP3, and OP4 may be spaced apart from each other with the first portion GF0 of the guide film GF therebetween. Alternatively, without being limited thereto, some of the first to fourth openings OP1, OP2, OP3, and OP4 may be integrally connected to each other. In an embodiment, for example, the first opening OP1 and the second opening OP2 may be integrally connected to each other and may be provided as (or defined by portions of) an opening having an L-shape.

FIG. 8A illustrates an embodiment that each of the first to fourth openings OP1, OP2, OP3, and OP4 has a quadrilateral shape in a plan view. Alternatively, without being limited thereto, the first to fourth openings OP1, OP2, OP3, and OP4 may have various shapes such as a circular shape, an oval shape, a polygonal shape other than a quadrilateral shape, and the like.

FIG. 8A illustrates an embodiment where the first to fourth openings OP1, OP2, OP3, and OP4 overlap the first to fourth bending portions BA-S1, BA-S2, BA-S3, and BA-S4, respectively. Alternatively, without being limited thereto, regions where openings are formed in the guide film GF may vary depending on the number and positions of bending portions of the display member DS. In an embodiment, for example, in which the display member DS includes a single bending portion, the guide film GF may include at least one opening in a region overlapping the single bending portion.

Embodiments illustrated in FIGS. 8B and 8C may have substantially the same configuration as the embodiment of the guide film GF of FIG. 8A, except for the arrangement and shape of the openings OP1, OP2, OP3, and OP4. The above description may be applied to the guide film GF, and the following description will be focused on the difference.

Referring to FIGS. 8B and 8C, a plurality of first openings OP1, a plurality of second openings OP2, a plurality of third openings OP3, and a plurality of fourth openings OP4 may be defined or provided in the guide film GF. The first openings OP1 may overlap the first bending portion BA-S1, the second openings OP2 may overlap the second bending portion BA-S2, the third openings OP3 may overlap the third bending portion BA-S3, and the fourth openings OP4 may overlap the fourth bending portion BA-S4.

Referring to FIG. 8B, in an embodiment, the first openings OP1 may extend in the first direction DR1 and may be arranged in the second direction DR2. The second openings OP2 may extend in the second direction DR2 and may be arranged in the first direction DR1. The third openings OP3 may extend in the first direction DR1 and may be arranged in the second direction DR2. The fourth openings OP4 may extend in the second direction DR2 and may be arranged in the first direction DR1.

Referring to FIG. 8C, in an alternative embodiment, the first openings OP1 may overlap the first bending portion BA-S1 and may be arranged in the first direction DR1 corresponding to the extension direction of the first bending portion BA-S1. The second openings OP2 may overlap the second bending portion BA-S2 and may be arranged in the second direction DR2 corresponding to the extension direction of the second bending portion BA-S2. The third openings OP3 may overlap the third bending portion BA-S3 and may be arranged in the first direction DR1, and the fourth openings OP4 may overlap the fourth bending portion BA-S4 and may be arranged in the second direction DR2.

The sum of the areas of openings overlapping one bending portion may be about 50% or greater of the area of the bending portion. In an embodiment, for example, the sum of the areas of the first openings OP1 may be about 50% or more of the area of the first bending portion BA-S1. Alternatively, without being limited thereto, the areas of the first openings OP1 may vary depending on the design of the modulus of the guide film GF overlapping the first bending portion BA-S1.

Although FIGS. 8B and 8C illustrate embodiment where openings overlapping one bending portion are arranged in one direction, the disclosure is not limited thereto. In an alternative embodiment, for example, the first openings OP1 overlapping the first bending portion BA-S1 may be arranged in a matrix form in the first direction DR1 and the second direction DR2, or may be arranged in an oblique direction crossing the first direction DR1 and the second direction DR2.

Referring to FIG. 8D, in another alternative embodiment, the opening OP may be expanded in the guide film GF such that the first to fourth extended portions GF1, GF2, GF3, and GF4 are spaced apart from each other. In such an embodiment, the first to fourth extended portions GF1, GF2, GF3, and GF4 may be spaced apart from each other with the opening OP therebetween. Accordingly, the opening OP of the guide film GF may overlap an entire region of the flat portion FA of the display member DS.

The first extended portion GF1 and the third extended portion GF3 may be spaced apart from each other in the second direction DR2 with the opening OP therebetween. That is, the first extended portion GF1 may be attached to the rear surface of the first bending portion BA-S1 that is adjacent to an end of the first bending portion BA-S1, and the third extended portion GF3 may be attached to the rear surface of the third bending portion BA-S3 that is adjacent to an end of the third bending portion BA-S3. The first extended portion GF1 and the third extended portion GF3 may be spaced apart from each other in a plan view with the flat portion FA therebetween.

The second extended portion GF2 and the fourth extended portion GF4 may be spaced apart from each other in the first direction DR1 with the opening OP therebetween. The second extended portion GF2 may be attached to the rear surface of the second bending portion BA-S2 that is adjacent to an end of the second bending portion BA-S2, and the fourth extended portion GF4 may be attached to the rear surface of the fourth bending portion BA-S4 that is adjacent to an end of the fourth bending portion BA-S4. The second extended portion GF2 and the fourth extended portion GF4 may be spaced apart from each other in a plan view with the flat portion FA therebetween.

The modulus of the guide film GF overlapping the bending portions BA-S1, BA-S2, BA-S3, and BA-S4 may be controlled or determined depending on the areas, shapes, and arrangements of the openings OP1, OP2, OP3, and OP4 formed in the guide film GF to overlap the bending portions BA-S1, BA-S2, BA-S3, and BA-S4. The modulus of the guide film GF may be changed depending on the design of the display member DS. Accordingly, the areas, shapes, and arrangements of the openings OP1, OP2, OP3, and OP4 are not limited to those illustrated in the drawings and may be diversely changed depending on the modulus of the guide film GF to be implemented.

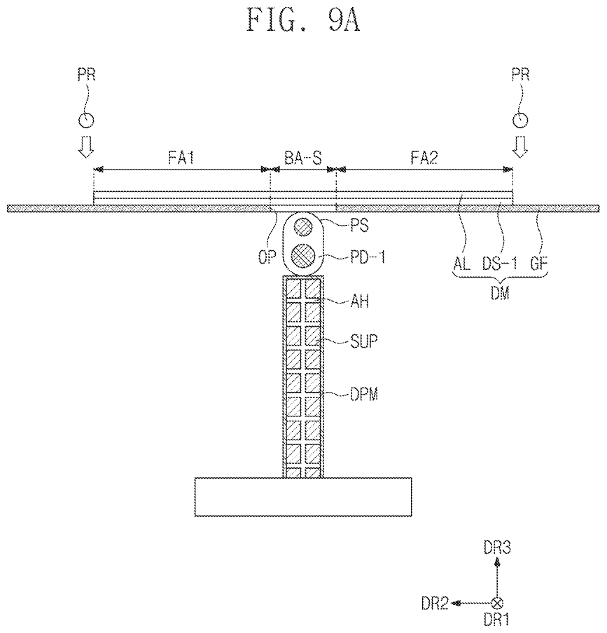

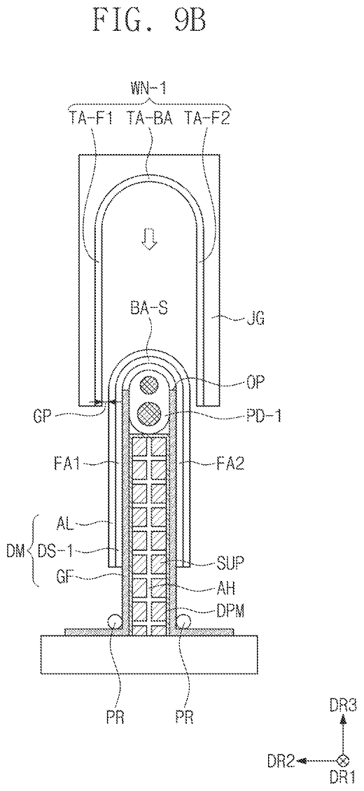

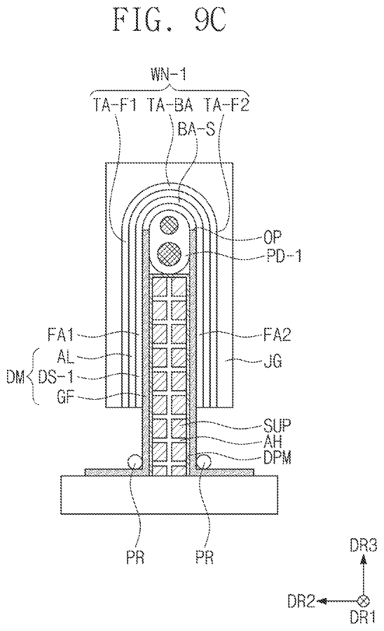

FIGS. 9A to 9C are sectional views illustrating a method of attaching a display module and a window member to each other according to an embodiment of the disclosure. Processes illustrated in FIGS. 9A to 9C may correspond to a process of manufacturing the display device DD-1 of FIG. 4.

Referring to FIGS. 9A to 9C, in an embodiment, the process of attaching the display module DM and the window member WN-1 to each other may include a process of providing the display module DM on a pressure pad PD-1.

The display module DM may include the display member DS-1, a guide film GF, and an adhesive layer AL. FIG. 9A illustrates a section of the display member DS-1 that corresponds to the first flat portion FA1, the bending portion BA-S, and the second flat portion FA2. The guide film GF may be attached to the rear surface of the display member DS-1. The adhesive layer AL may be disposed on the upper surface of the display member DS-1. Alternatively, without being limited thereto, the adhesive layer AL may be disposed on the lower surface of the window member WN-1 that is to be provided on the display module DM.

An opening OP may be defined or formed through the guide film GF. The opening OP of the guide film GF may overlap the bending portion BA-S of the display member DS-1.

The pressure pad PD-1 may include a material that is easily deformed by pressure. In an embodiment, for example, the pressure pad PD-1 may include an elastic material such as silicone.

The pressure pad PD-1 may have a tower shape having a long axis extending in the third direction DR3. The pressure pad PD-1 may include a pressure surface PS including a curved surface that is convex upward. The curved surface of the pressure surface PS may overlap the bending portion BA-S of the display member DS-1 and may support the bending portion BA-S.

A support part SUP and a diaphragm DPM may be disposed under the pressure pad PD-1. A through-hole AH may be defined in the support part SUP. The through-hole AH may be a passage through which air moves. The through-hole AH may include a main hole extending in the third direction DR3 and sub-holes extending from the main hole in the second direction DR2. In such an embodiment, the sub-holes of the through-hole AH may extend toward opposite side surfaces of the support part SUP. The diaphragm DPM may cover the support part SUP.

The display module DM may be fixed to a clamp and may be provided on the pressure pad PD-1. In an embodiment, for example, the clamp may clamp the guide film GF, and the display member DS-1 attached to the guide film GF may be indirectly fixed through the guide film GF and may be disposed on the pressure pad PD-1. Accordingly, the display member DS-1 may be effectively prevented from being damaged by the clamp.

Pressing parts PR may be provided on the display module DM. The pressing parts PR may have a rod shape extending in the first direction DR1. The pressing parts PR may fix the guide film GF such that the guide film GF is brought into close contact with the pressure pad PD-1 in a process in which the guide film GF is brought into contact with the pressure pad PD-1 to correspond to the shape of the pressure pad PD-1. That is, the pressing parts PR may bring the guide film GF into close contact with the pressure pad PD-1 and the diaphragm DMP while moving toward the support part SUP in a direction parallel to the second direction DR2.

Since the guide film GF is brought into close contact with side surfaces of the diaphragm DPM and the pressure pad PD-1, the bending portion BA-S of the display member DS-1 may be bent to correspond to the shape of the curved surface of the pressure surface PS of the pressure pad PD-1. The first flat portion FA1 of the display member DS-1 may overlap one side surface of the diaphragm DPM, and the second flat portion FA2 of the display member DS-1 may overlap an opposite side surface of the diaphragm DPM. The adhesive layer AL disposed on the display member DS-1 may have a shape corresponding to the shape of the display member DS-1.

The process of attaching the display module DM and the window member WN-1 to each other may include a process of providing a jig JG with the window member WN-1 disposed thereon on the display module DM. The window member WN-1 may have a shape corresponding to the shape of a receiving recess formed in the jig JG and may be fixedly disposed in the receiving recess. The window member WN-1 may include the first flat transmissive surface TA-F1, the second flat transmissive surface TA-F2, and the bending transmissive surface TA-BA that correspond to the first flat portion FA1, the second flat portion FA2, and the bending portion BA-S of the display member DS-1, respectively.

The jig JG in which the window member WN-1 is accommodated may move toward the display module DM disposed on the pressure pad PD-1. When the window member WN-1 makes contact with the display member DS-1 and the pressure pad PD-1, the support part SUP, and the diaphragm DPM are thereby inserted into the space between the first flat transmissive surface TA-F1 and the second flat transmissive surface TA-F2 of the window member WN-1 due to on the movement of the jig JG, the display member DS-1 may be caught and may be attached to an inappropriate position of the window member WN-1. In an embodiment, the window member WN-1 may be provided to have a predetermined gap GP with the display member DS-1 to prevent the display member DS-1 from being caught.

Since the guide film GF is provided with the opening OP overlapping the bending portion BA-S of the display member DS-1, the gap desired for the attachment process may be provided or formed between the display member DS-1 and the window member WN-1. Accordingly, a defect may be effectively prevented in the process of attaching the display member DS-1 and the window member WN-1, and process reliability may be improved.

The jig JG, the pressure pad PD-1, the support part SUP, and the diaphragm DMP may press the window member WN-1 and the display module DM spaced apart from each other by the predetermined gap GP and may attach the window member WN-1 and the display module DM to each other. The window member WN-1 and the display member DS-1 may be attached to each other through the adhesive layer AL. The first flat transmissive surface TA-F1 of the window member WN-1 may be attached to the first flat portion FA1 of the display member DS-1, and the second flat transmissive surface TA-F2 of the window member WN-1 may be attached to the second flat portion FA2 of the display member DS-1. The bending transmissive surface TA-BA of the window member WN-1 that includes a curved surface may be attached to the bending portion BA-S of the display member DS-1.

Since the guide film GF is provided with the opening OP overlapping the bending portion BA-S of the display member DS-1, the modulus of the guide film GF overlapping the bending portion BA-S may be less than the modulus of the guide film GF overlapping the flat portions FA1 and FA2. Since the guide film GF is provided with the opening OP, a neutral surface NP (refer to FIG. 7A) may be defined in the display member DS-1 in a process in which the bending portion BA-S of the display member DS-1 is bent. Accordingly, components of the display member DS-1 may be effectively prevented from being damaged by stress such as tensile stress caused by bending.

In an embodiment, after the window member WN-1 and the display member DS-1 of the display module DM are attached to each other, the guide film GF may be removed from the display member DS-1. Accordingly, the finally manufactured display device DD-1 (refer to FIG. 3A) may include the display member DS-1 from which the guide film GF is removed. Thus, the guide film GF including the opening OP may effectively prevent a defect in the attachment process of the display member DS-1 and the window member WN-1 without affecting the manufactured display member DS-1.

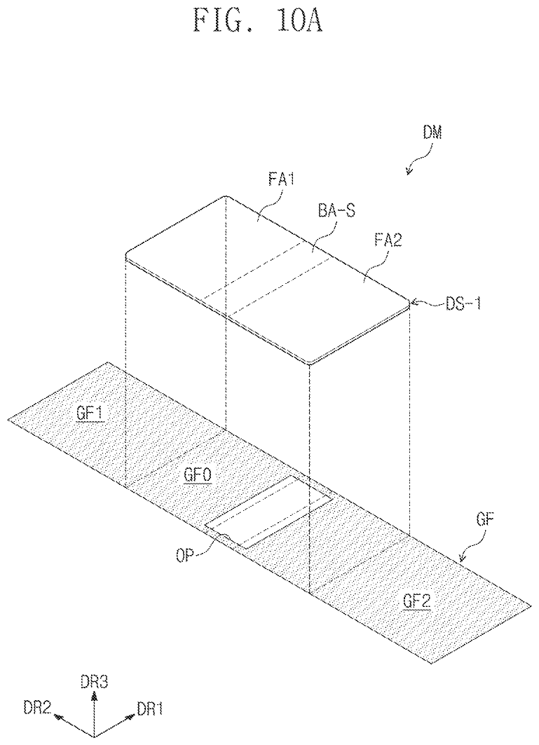

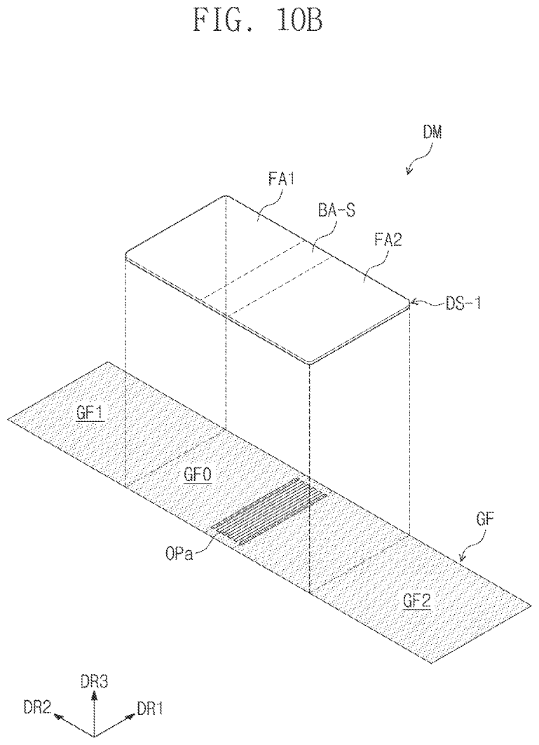

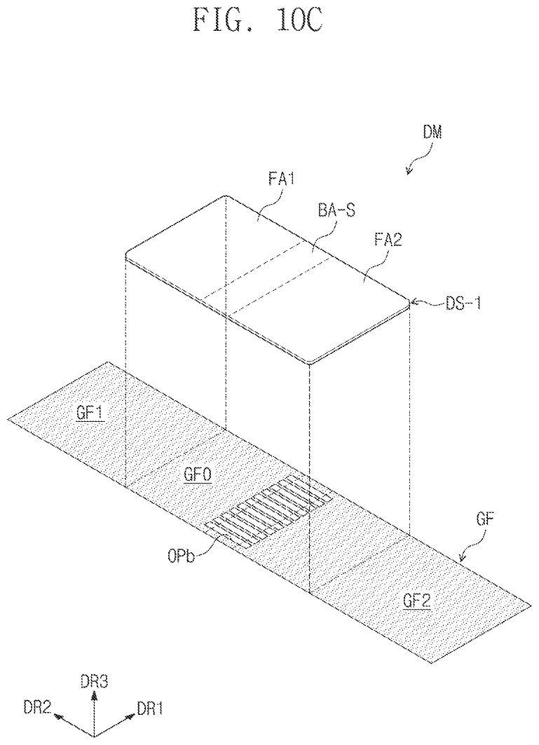

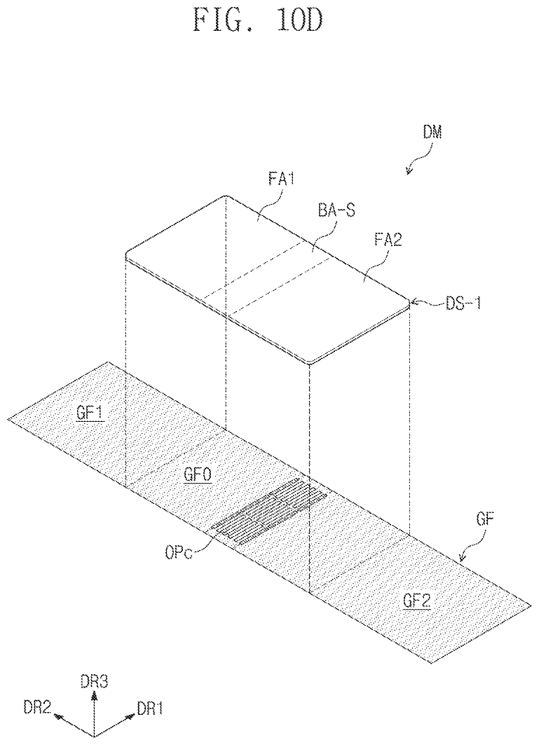

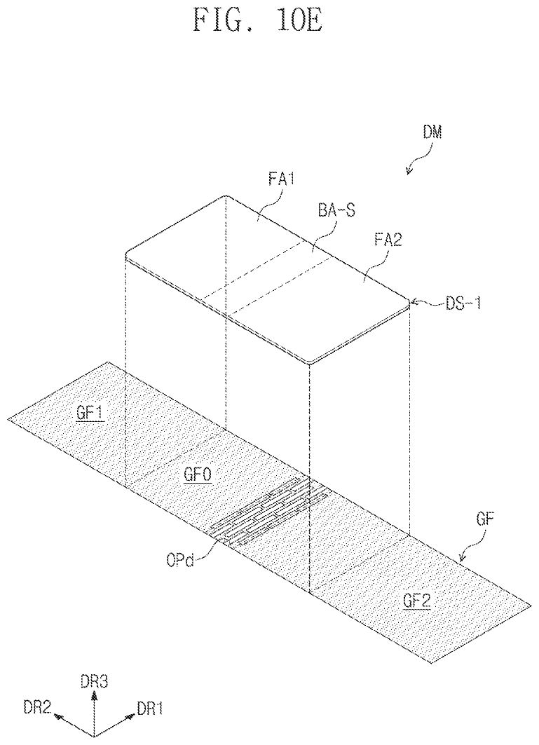

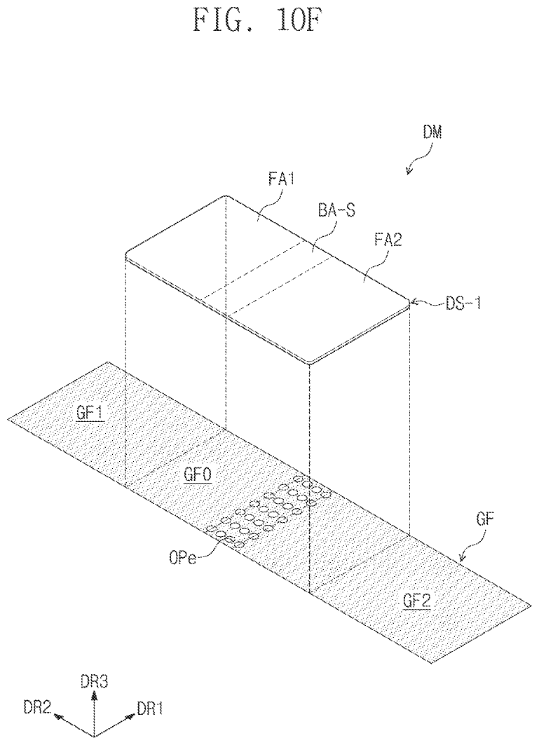

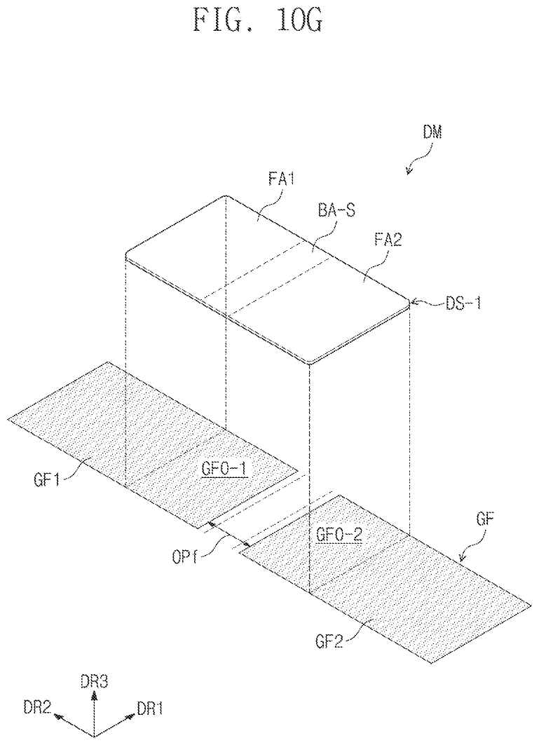

FIGS. 10A to 10G are perspective views of the display module DM according to embodiments of the disclosure. FIGS. 10A to 10G illustrate various embodiments of an opening defined in the guide film GF.

The display member DS-1 included in the display module DM of FIGS. 10A to 10G may correspond to the display member DS-1 of FIG. 4, and the above description may be identically applied.

Referring to FIG. 10A, in an embodiment, the display module DM may include the display member DS-1 and the guide film GF disposed on the rear surface of the display member DS-1. The guide film GF may include extended portions extending outward of edges from the display member DS-1 in a plan view. The guide film GF may be provided with a first portion GF0 overlapping the display member DS-1 and first and second extended portions GF1 and GF2 extending from the first portion GF0.

The first extended portion GF1 may extend in a direction parallel to the second direction DR2 from a first side of the first portion GF0 parallel to the first direction DR1. The second extended portion GF2 may extend in a direction parallel to the second direction DR2 from a second side of the first portion GF0 that is parallel to the first direction DR1 and faces the first side. The first extended portion GF1 and the second extended portion GF2 may be spaced apart from each other in the second direction DR2 with the first portion GF0 therebetween.

The first portion GF0 of the guide film GF may overlap the first flat portion FA1, the bending portion BA-S, and the second flat portion FA2 of the display member DS-1. The opening OP overlapping the bending portion BA-S may be defined or formed in the first portion GF0 of the guide film GF.

The area of the opening OP may be about 50% or greater of the area of the bending portion BA-S. Alternatively, without being limited thereto, the area of the opening OP may vary depending on the modulus of the guide film GF overlapping the bending portion BA-S.

The opening OP may extend in the first direction DR1 corresponding to the extension direction of the overlapping bending portion BA-S. A width of the opening OP in the second direction DR2 may be greater than a width of the bending portion BA-S in the second direction DR2. Accordingly, a boundary between the first flat portion FA1 and the bending portion BA-S and a boundary between the second flat portion FA2 and the bending portion BA-S may overlap the opening OP. However, embodiments are not limited thereto.

Embodiments of FIGS. 10B to 10G may have substantially the same configuration as the embodiment of the guide film GF of FIG. 10A, except for the arrangement and shape of the opening. The above description may be applied to the guide film GF, and the following description will be focused on the difference.

Referring to FIG. 10B, in an alternative embodiment, a plurality of openings Opa may be provided in the guide film GF. In such an embodiment, the openings Opa may extend in the first direction DR1. The openings Opa may be arranged in the second direction DR2 in the region overlapping the bending portion BA-S. Although FIG. 10B illustrates an embodiment the openings Opa have a same length and width as each other, some of the openings Opa may have different lengths or widths.

Referring to FIG. 10C, in another alternative embodiment, a plurality of openings Opb may be provided in the guide film GF. In such an embodiment, the openings Opb may extend in the second direction DR2. The openings Opb may be arranged in the first direction DR1 in the region overlapping the bending portion BA-S. The lengths of the openings Opb in the second direction DR2 may be greater than the width of the bending portion BA-S in the second direction DR2. However, embodiments are not limited thereto.

Referring to FIG. 10D, in another alternative embodiment, a plurality of openings Opc may be provided in the guide film GF. In such an embodiment, the openings Opc may extend in the first direction DR1. The openings Opc may be arranged in the first direction DR1 and the second direction DR2 in the region overlapping the bending portion BA-S. That is, the openings Opc may include a plurality of groups, each of which includes openings Opc arranged parallel to the first direction DR1, and the plurality of groups of openings Opc may be arranged side by side in the second direction DR2.

Referring to FIG. 10E, in another alternative embodiment, a plurality of openings Opd may be provided in the guide film GF. In such an embodiment, the openings Opd may extend in the first direction DR1. The openings Opd may be arranged in a staggered pattern in the first direction DR1 in the region overlapping the bending portion BA-S. That is, the openings Opd may include a plurality of groups, each of which includes openings Opd arranged parallel to the first direction DR1, and groups adjacent to each other in the second direction DR2 among the plurality of groups may be staggered with respect to each other in the first direction DR1.

Referring to FIG. 10F, in another alternative embodiment, a plurality of openings Ope may be provided in the guide film GF. In such an embodiment, the openings Ope may be arranged in a matrix form in the first direction DR1 and the second direction DR2 in the region overlapping the bending portion BA-S. The openings Ope may have a circular shape in a plan view. Alternatively, without being limited thereto, the openings Ope may have an oval shape or a polygonal shape such as a quadrilateral shape.

In such an embodiment, the sum of the areas of openings overlapping one bending portion BA-S may be about 50% or greater of the area of the bending portion BA-S. Alternatively, without being limited thereto, the areas of the openings may vary depending on the design of the modulus of the guide film GF overlapping the bending portion BA-S.

Referring to FIG. 10G, in another alternative embodiment, an opening Opf may be expanded toward the opposite ends of the guide film GF such that the first portion of the guide film GF includes a first sub-portion GF0-1 and a second sub-portion GF0-2 spaced apart from each other with the opening Opf therebetween. The first sub-portion GF0-1 and the second sub-portion GF0-2 may be spaced apart from each other in the second direction DR2 with the opening Opf therebetween. The first sub-portion GF0-1 may overlap the first flat portion FA1.

The first extended portion GF1 may extend from one end of the first sub-portion GF0-1 in a direction parallel to the second direction DR2. The second sub-portion GF0-2 may overlap the second flat portion FA2. The second extended portion GF2 may extend from one end of the second sub-portion GF0-2 in a direction parallel to the second direction DR2.

The opening Opf may have the same length as the guide film GF in the first direction DR1. The width of the opening Opf in the second direction DR2 may be greater than the width of the bending portion BA-S in the second direction DR2. However, embodiments are not limited thereto.

The modulus of the guide film GF overlapping the bending portion BA-S may be controlled or determined depending on the areas, shapes, and arrangements of the openings formed in the guide film GF to overlap the bending portion BA-S, and the modulus of the guide film GF may be set depending on the design of the display member DS-1. Accordingly, the areas, shapes, and arrangements of the openings are not limited to those illustrated in the drawings and may be diversely changed depending on the modulus of the guide film GF to be implemented.

In embodiment of the disclosure, as described above, the display module may include the guide film provided with the opening defined therein to overlap the bending region, and thus the display panel in the display module may be effectively prevented from being damaged by bending the display module.

In such embodiments, since the display module includes the guide film provided with the opening overlapping the bending region, the predetermined gap may be provided or formed between the display module and the window member in the bending region in the process of attaching the display module and the window member. Thus, the display module may be effectively prevented from being caught during a process of attaching the display module and a window member to each other, and a problem that the display module fails to adhere to the window member may be effectively prevented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display module comprising:
a display member including a flat portion and a bending portion bent while extending from the flat portion; and
a guide film disposed on a rear surface of the display member, wherein the guide film including an extended portion extending from an edge of the display member in a plan view,
wherein the guide film is provided with an opening defined therein to overlap the bending portion of the display module.

2. The display module of claim 1, wherein the flat portion includes a first side extending in a first direction, and
wherein the bending portion includes a first bending portion bent while extending from the first side of the flat portion.

3. The display module of claim 2, wherein the flat portion includes a second side extending in the first direction and opposite to the first side in a second direction crossing the first direction, and
wherein the bending portion further includes a second bending portion bent while extending from the second side of the flat portion.

4. The display module of claim 3, wherein the flat portion includes a third side and a fourth side extending in the second direction and opposite to each other in the first direction, and
wherein the bending portion further includes a third bending portion and a fourth bending portion bent while extending from the third side and the fourth side of the flat portion, respectively.

5. The display module of claim 4, wherein the opening includes first to fourth openings which overlap the first to fourth bending portions, respectively.

6. The display module of claim 5, wherein the first opening and the second opening extend in the first direction, and the third opening and the fourth opening extend in the second direction.

7. The display module of claim 6, wherein the first opening is provided in plural, and a plurality of first openings is arranged in the second direction while overlapping the first bending portion.

8. The display module of claim 5, wherein the first opening is provided in plural and each of a plurality of first openings extends in the second direction, and
wherein the first openings are arranged in the first direction while overlapping the first bending portion.

9. The display module of claim 4, wherein the guide film includes first to fourth extended portions disposed on rear surfaces of the first to fourth bending portions, respectively,
wherein the first extended portion and the second extended portion are spaced apart from each other in the second direction with the flat portion therebetween, and
wherein the third extended portion and the fourth extended portion are spaced apart from each other in the first direction with the flat portion therebetween.

10. The display module of claim 1, wherein the flat portion includes a first flat portion and a second flat portion which overlap each other in a plan view, and
wherein the bending portion is disposed between the first flat portion and the second flat portion and connected to the first flat portion and the second flat portion.

11. The display module of claim 10, wherein the bending portion extends in a first direction, and the opening extends in the first direction.

12. The display module of claim 11, wherein a length of the opening is shorter than a length of the bending portion in the first direction.

13. The display module of claim 11, wherein a width of the opening is greater than a width of the bending portion in a second direction crossing the first direction.

14. The display module of claim 11, wherein the opening extends to opposite ends of the guide film in the first direction, and the guide film includes a plurality of portions spaced apart from each other with the opening therebetween.

15. The display module of claim 11, wherein the opening is provided in plural, and a plurality of openings is arranged in a second direction crossing the first direction.

16. The display module of claim 10, wherein the bending portion extends in a first direction, and
wherein the opening is provided in plural, and each of a plurality of openings extends in a second direction crossing the first direction, and
wherein the openings are arranged in the first direction.

17. The display module of claim 1, wherein the display member includes:
a base layer;
a circuit layer disposed on the base layer;
a display element layer disposed on the circuit layer; and
an encapsulation layer sealing the display element layer.

18. The display module of claim 17, wherein the display member further includes at least one selected from an input sensing layer and an anti-reflection layer disposed on the encapsulation layer.

19. The display module of claim 1, further comprising:
an adhesive layer disposed on the display member; and
a window member disposed on the adhesive layer.

20. A method for attaching a display module and a window member to each other, the method comprising:
providing a pressure pad including a pressure surface including a curved surface;
providing the display module including an adhesive layer, a display member, and a guide film on the pressure pad;
providing a jig with the window member disposed thereon on the display module; and
attaching the display module and the window member to each other through the adhesive layer,
wherein the display member includes a bending portion overlapping the curved surface of the pressure pad, and the guide film is provided with an opening defined therein to overlap the bending portion of the display member.
